(19) United States
(12) Patent Application Publication
(10) Pub. No.: US 2025/0336427 A1
(43) Pub. Date: Oct. 30, 2025

(54) MEMORY DEVICES AND OPERATION METHOD THEREOF

(71) Applicant: YANGTZE MEMORY TECHNOLOGIES CO., LTD., Wuhan (CN)

(72) Inventors: Wang HE, Wuhan (CN); Debo WEI, Wuhan (CN); Ling DING, Wuhan (CN); HuangPeng ZHANG, Wuhan (CN)

(21) Appl. No.: 19/013,972

(22) Filed: Jan. 8, 2025

(30) Foreign Application Priority Data
Apr. 30, 2024 (CN) 2024105450338

(51) Int. Cl. G11C 8/18; G11C 7/10; G11C 7/22

(52) U.S. Cl. CPC G11C 8/18; G11C 7/106; G11C 7/1066; G11C 7/222

(57) ABSTRACT

Examples of the present disclosure provide memory devices and an operation method thereof. The memory device includes: a memory cell array; a control logic circuit coupled with the memory cell array and configured to receive a command address signal, output a first control signal at a first time instant, and output a second control signal at a second time instant, wherein the first time instant is different from the second time instant; and a clock generation circuit configured to receive a first clock signal, the first control signal and the second control signal, be pre-charged according to the first control signal, and perform frequency division processing on the first clock signal according to the second control signal to output a second clock signal, wherein the first clock signal is different from the second clock signal.

### CROSS-REFERENCE TO RELATED APPLICATIONS

This application claims the benefit of priority to China Patent Application No. CN 2024105450338, filed on Apr. 30, 2024, which is incorporated herein by reference in its entirety.

### TECHNICAL FIELD

Examples of the present disclosure relate to the technical field of semiconductors, and more particularly, to a memory device and an operation method thereof.

### BACKGROUND

Memory devices and systems thereof are storage apparatuses for storing information in the modern information technology. With the increasingly high requirements for the storage apparatuses, there may still be much room for improvements in the memory devices and the systems thereof.

### SUMMARY

In view of this, examples of the present disclosure provide memory devices and an operation method thereof.

According to one aspect of the present disclosure provide a memory device. The memory device comprises: a memory cell array; a control logic circuit coupled with the memory cell array and configured to receive a command address signal, output a first control signal at a first time instant, and output a second control signal at a second time instant, wherein the first time instant is different from the second time instant; and a clock generation circuit configured to receive a first clock signal, the first control signal and the second control signal, be pre-charged according to the first control signal, and perform frequency division processing on the first clock signal according to the second control signal to output a second clock signal, wherein the first clock signal is different from the second clock signal.

In some examples, the first time instant comprises a time instant when the command address signal is received or a time instant thereafter, and the first time instant is earlier than the second time instant.

In some examples, the control logic circuit comprises: a first latch circuit configured to receive the command address signal, and output the first control signal at the first time instant; a delay circuit configured to receive the command address signal, and output a latency count signal at the second time instant; and a second latch circuit configured to receive the latency count signal, and output the second control signal.

In some examples, the first latch circuit is configured such that the first control signal outputted at the first time instant starts to be in a first logic state, and according to the first control signal starting to be in the first logic state, the clock generation circuit starts to be pre-charged; and the second latch circuit is configured such that the second control signal outputted at the second time instant starts to be in an activated state, and according to the second control signal starting to be in the activated state, the clock generation circuit starts to receive the first clock signal and output the second clock signal.

In some examples, the delay circuit is further configured to receive the command address signal, and output a reset signal at a third time instant, wherein the third time instant is later than the second time instant; the first latch circuit is further configured to receive the reset signal, and switch the first control signal outputted at the third time instant to be in a second logic state, and according to the first control signal starting to be in the second logic state, the clock generation circuit finishes being pre-charged; and the second latch circuit is further configured to receive the reset signal, and switch the second control signal outputted at the third time instant to be in a non-activated state, and according to the second control signal being in the non-activated state, the clock generation circuit stops outputting the second clock signal.

In some examples, the first latch circuit comprises a first RS latch, the first RS latch having a reset terminal to receive the reset signal, a set terminal to receive the command address signal, and an output terminal to output the first control signal; and/or the second latch circuit comprises a second RS latch, the second RS latch having a reset terminal to receive the reset signal, a set terminal to receive the latency count signal, and an output terminal to output the second control signal.

In some examples, the delay circuit comprises: a first clock delay unit configured to receive the command address signal, and output the latency count signal after a first preset duration; and a second clock delay unit configured to receive the command address signal, and output the reset signal after a second preset duration, wherein the first preset duration is a difference between the second time instant and the time instant when the command address signal is received, and the second preset duration is a difference between the third time instant and the time instant when the command address signal is received.

In some examples, the clock generation circuit comprises: an input buffer configured to receive the first clock signal, the first control signal and the second control signal, start to be pre-charged according to the first control signal, and start to transmit the first clock signal according to the second control signal; and a frequency divider configured to receive the first clock signal transmitted by the input buffer, perform frequency division processing on the received first clock signal transmitted by the input buffer to output the second clock signal.

In some examples, the first clock signal comprises a pair of differential clock signals, and the second clock signal comprises clock signals of four phases with a phase difference of 90 degrees in sequence; the frequency divider is configured to perform frequency division on the pair of differential clock signals to output the clock signals of four phases, wherein the clock signals of four phases comprise a third clock signal and a third complementary clock signal having a phase difference of 180 degrees relative to each other, and a fourth clock signal and a fourth complementary clock signal having a phase difference of 180 degrees relative to each other, wherein the third clock signal and the fourth clock signal have a phase difference of 90 degrees relative to each other; and wherein two signals having a phase difference of 90 degrees from among the third clock signal, the third complementary clock signal, the fourth clock signal and the fourth complementary clock signal are for outputting data from the memory cell array.

In some examples, the clock generation circuit further comprises: a synchronization detector configured to receive the two signals, and output a detection signal according to the phase difference between the two signals, wherein the detection signal is to represent whether or not the two signals have a phase difference of 90 degrees relative to each other.

In some examples, any one of the memory devices in the above-mentioned various examples comprises a dynamic random access memory.

According to another aspect, the present disclosure provide another memory device. The memory device comprises: a first latch circuit includes a first input terminal to receive a command address signal, and an output terminal to output a first control signal at a first time instant; a delay circuit having an input terminal to receive the command address signal, and a first output terminal to output a latency count signal at a second time instant, wherein the first time instant is different from the second time instant; a second latch circuit having a first input terminal connected to the first output terminal of the delay circuit to receive the latency count signal, and an output terminal to output a second control signal at the second time instant; and a clock generation circuit having a first input terminal to receive a first clock signal, a second input terminal connected to the output terminal of the first latch circuit to receive the first control signal, a third input terminal connected to the output terminal of the second latch circuit to receive the second control signal, and an output terminal to output a second clock signal, wherein the first control signal is to indicate a start of pre-charging, the second control signal is to indicate a start of frequency division processing on the first clock signal, and the first clock signal is different from the second clock signal.

In some examples, the first control signal outputted by the output terminal of the first latch circuit at the first time instant starts to be in a first logic state, and the clock generation circuit receives, at the second input terminal of the clock generation circuit, the first control signal starting to be in the first logic state and starts to be pre-charged; and the second control signal outputted by the output terminal of the second latch circuit at the second time instant starts to be in an activated state, and the clock generation circuit receives, at the third input terminal of the clock generation circuit, the second control signal starting to be in the activated state, receives the first clock signal at the first input terminal of the clock generation circuit, and outputs the second clock signal at the output terminal of the clock generation circuit.

In some examples, a second output terminal of the delay circuit outputs a reset signal at a third time instant, wherein the third time instant is later than the second time instant; a second input terminal of the first latch circuit is connected to the second output terminal of the delay circuit to receive the reset signal, and the first control signal outputted by the output terminal of first latch circuit at the third time instant is switched to be in a second logic state, and the clock generation circuit receives, at the second input terminal of the clock generation circuit, the first control signal starting to be in the second logic state and finishes being pre-charged; and a second input terminal of the second latch circuit is connected to the second output terminal of the delay circuit to receive the reset signal, and the second control signal outputted by the output terminal of the second latch circuit at the third time instant is switched to be in a non-activated state, and the clock generation circuit receives, at the third input terminal of the clock generation circuit, the second control signal being in the non-activated state and stops outputting the second clock signal.

In some examples, the first latch circuit comprises a first RS latch, the first RS latch having a reset terminal to receive the reset signal, a set terminal to receive the command address signal, and an output terminal to output the first control signal; and/or the second latch circuit comprises a second RS latch, the second RS latch having a reset terminal to receive the reset signal, a set terminal to receive the latency count signal, and an output terminal to output the second control signal.

In some examples, the delay circuit comprises: a first clock delay unit having an input terminal to receive the command address signal, and an output terminal to output the latency count signal after a first preset duration; and a second clock delay unit having an input terminal to receive the command address signal, and an output terminal to output the reset signal after a second preset duration, wherein the first preset duration is a difference between the second time instant and the time instant when the command address signal is received, and the second preset duration is a difference between the third time instant and the time instant when the command address signal is received.

In some examples, the clock generation circuit comprises: an input buffer having a first input terminal to receive the first clock signal, a second input terminal connected to the output terminal of the first latch circuit to receive the first control signal, a third input terminal connected to the output terminal of the second latch circuit to receive the second control signal, and an output terminal to transmit the first clock signal; and a frequency divider having an input terminal connected to the output terminal of the input buffer to receive the first clock signal transmitted by the input buffer, and an output terminal to output the second clock signal, wherein the first clock signal comprises a pair of differential clock signals, the second clock signal comprises clock signals of four phases with a phase difference of 90 degrees in sequence, and two signals having a phase difference of 90 degrees from among the clock signals of four phases are for outputting data from a memory cell array.

According to another aspect, the present disclosure provide an operation method of a memory device. The operation method comprises: receiving, by a control logic circuit coupled with a memory cell array, a command address signal, outputting a first control signal at a first time instant, and outputting a second control signal at a second time instant, wherein the first time instant is different from the second time instant; and receiving, by a clock generation circuit, a first clock signal, the first control signal and the second control signal, being pre-charged according to the first control signal, and performing frequency division processing on the first clock signal according to the second control signal to output a second clock signal, wherein the first clock signal is different from the second clock signal.

In some examples, the operation method comprises: receiving, by a first latch circuit of the control logic circuit, the command address signal and outputting the first control signal at the first time instant; receiving, by a delay circuit of the control logic circuit, the command address signal and outputting a latency count signal at the second time instant; and receiving, by a second latch circuit of the control logic circuit, the latency count signal and outputting the second control signal.

In some examples, the operation method comprises: the first control signal outputted by the first latch circuit at the first time instant starts to be in a first logic state, and according to the first control signal starting to be in the first logic state, the clock generation circuit starts to pre-charged; and the second control signal outputted by the second latch circuit at the second time instant starts to be in an activated state, and according to the second control signal starting to be in the activated state, the clock generation circuit starts to receive the first clock signal and output the second clock signal.

In some examples, the operation method further comprises: outputting, by the delay circuit, a reset signal at a third time instant, wherein the third time instant is later than the second time instant; receiving, by the first latch circuit, the reset signal and switching the first control signal outputted at the third time instant to be in a second logic state, and according to the first control signal starting to be in the second logic state, the clock generation circuit finishes being pre-charged; and receiving, by the second latch circuit, the reset signal and switching the second control signal outputted at the third time instant to be in a non-activated state, and according to the second control signal being in the non-activated state, the clock generation circuit stops outputting the second clock signal.

In some examples, the operation method comprises: receiving, by an input buffer of the clock generation circuit, the first clock signal, the first control signal and the second control signal, starting to be pre-charged according to the first control signal, and starting to transmit the first clock signal according to the second control signal; and receiving, by a frequency divider of the clock generation circuit, the first clock signal transmitted by the input buffer, performing frequency division processing on the received first clock signal transmitted by the input buffer to output the second clock signal.

In some examples, the operation method comprises: performing, by the frequency divider, frequency division on a pair of differential clock signals of the first clock signal to output clock signals of four phases of the second clock signal, wherein the clock signals of four phases comprise a third clock signal and a third complementary clock signal having a phase difference of 180 degrees relative to each other, and a fourth clock signal and a fourth complementary clock signal having a phase difference of 180 degrees relative to each other, wherein the third clock signal and the fourth clock signal have a phase difference of 90 degrees relative to each other, and wherein two signals having a phase difference of 90 degrees from among the third clock signal, the third complementary clock signal, the fourth clock signal and the fourth complementary clock signal are used to output data from the memory cell array.

In some examples, the operation method further comprises: receiving, by a synchronization detector of the clock generation circuit, the two signals and outputting a detection signal according to the phase difference between the two signals, wherein the detection signal is to represent whether or not the two signals have a phase difference of 90 degrees relative to each other.

In the examples of the present disclosure, the pre-charging and the enabling of the clock generation circuit of the memory device can be controlled respectively by the first control signal and the second control signal generated by the control logic circuit of the memory device, such that the limitation that the clock generation circuit has a shorter pre-charging duration is mitigated, and the output of the clock generation circuit has enough time to stabilize, thereby reducing pre-charging delay. The clock generation circuit can provide a better duty cycle for the first clock signal. When receiving an active signal, the clock generation circuit is faster to respond, and the pre-charging duration of the clock generation circuit is no longer limited by the enabling duration of the clock generation circuit, thereby improving the data transmission efficiency.

### BRIEF DESCRIPTION OF THE DRAWINGS

FIG. 1 is a schematic diagram of a memory device in which both the pre-charging and the enabling of a clock generation circuit are controlled by a second control signal, provided by examples of the present disclosure;

FIG. 2 is a schematic diagram of the timing of various signals of the memory device of FIG. 1;

FIG. 3 is a schematic diagram I of the timing of outputting a second clock signal according to a first clock signal of FIG. 2;

FIG. 4 is a schematic diagram II of the timing of outputting a second clock signal according to a first clock signal of FIG. 2;

FIG. 5 is a schematic diagram I of a memory device in which the pre-charging and the enabling of a clock generation circuit are controlled respectively by a first control signal and a second control signal, provided by examples of the present disclosure;

FIG. 6 is a schematic diagram II of a memory device in which the pre-charging and the enabling of a clock generation circuit are controlled respectively by a first control signal and a second control signal, provided by examples of the present disclosure;

FIG. 7 is a schematic diagram III of a memory device in which the pre-charging and the enabling of a clock generation circuit are controlled respectively by a first control signal and a second control signal, provided by examples of the present disclosure;

FIG. 8 is a schematic diagram IV of a memory device in which the pre-charging and the enabling of a clock generation circuit are controlled respectively by a first control signal and a second control signal, provided by examples of the present disclosure;

FIG. 9 is a schematic diagram of a first latch circuit provided by examples of the present disclosure;

FIG. 10 is a schematic diagram of a second latch circuit provided by examples of the present disclosure;

FIG. 11 is a schematic diagram of a delay circuit provided by examples of the present disclosure;

FIG. 12 is a schematic diagram of a first clock delay unit provided by examples of the present disclosure;

FIG. 13 is a schematic diagram of a clock generation circuit provided by examples of the present disclosure;

FIG. 14 is a schematic diagram I of the timing of various signals of the memory device of FIG. 5;

FIG. 15 is a schematic diagram II of the timing of various signals of the memory device of FIG. 5;

FIG. 16 is a flow block diagram of an operation method of a memory device provided by examples of the present disclosure;

FIG. 17 shows a block diagram I of an example system having a memory device according to some aspects of the present disclosure;

FIG. 18 shows a block diagram II of an example system having a memory device according to some aspects of the present disclosure; and

FIG. 19 shows a block diagram III of an example system having a memory device according to some aspects of the present disclosure.

### DETAILED DESCRIPTION

The technical solutions in implementations of the present disclosure will be described below clearly and comprehensively in conjunction with the implementations and the drawings of the present disclosure. Apparently, those implementations described herein are only part of, but not all of, the implementations of the present disclosure. All other implementations obtained by those of ordinary skill in the art based on the implementations in the present disclosure without creative work shall fall within the scope of protection of the present disclosure.

In the description below, a large amount of details are presented to provide a more thorough understanding of the present disclosure. However, it is apparent to those skilled in the art that the present disclosure may be implemented without one or more of these details. In other examples, in order to avoid obscuring the present disclosure, some technical features well-known in the art are not described. That is, not all the features of the examples are described herein, and well-known functions and structures are not described herein in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or there may be intervening elements or layers. In contrast, when an element is referred to as being “directly on”, “immediately adjacent to”, “directly connected to”, or “directly coupled to” other elements or layers, no intervening elements or layers are present. It is to be understood that, although such terms as first, second, third and the like may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teaching of the present disclosure, a first element, component, region, layer or section discussed below may be represented as a second element, component, region, layer or section. When a second element, component, region, layer or section is discussed, it does not mean that the first element, component, region, layer or section is necessarily present in the present disclosure.

The terms used herein are only intended to describe the examples, and are not used as limitations of the present disclosure. As used herein, unless otherwise indicated expressly in the context, the singular forms “a”, “an” and “the” are also intended to comprise the plural forms. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to understand the present disclosure thoroughly, detailed steps and detailed structures will be proposed in the following description to set forth the technical solutions of the present disclosure. The detailed descriptions of the preferred examples of the present disclosure are as follows. However, the present disclosure may also have other implementations in addition to these detailed descriptions.

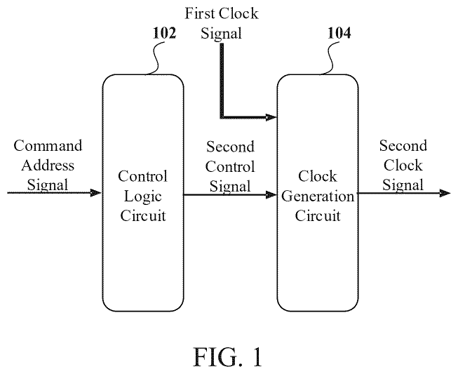

Referring to FIGS. 1, 2 and 3, a clock generation circuit 104 of a memory device may be triggered by a command address signal CAS CMD received by a control logic circuit 102 of the memory device, and both the pre-charging and the enabling of the clock generation circuit 104 may be controlled by a second control signal ws_actv. After a second duration tWCKENL has elapsed after the command address signal CAS CMD is received by the control logic circuit 102 of the memory device, the clock generation circuit 104 may be pre-charged and enabled based on the second control signal, wherein the second duration tWCKENL is a duration from a time instant when the command address signal CAS CMD is received (the initial time instant t0) to a second time instant t2, and the second duration tWCKENL is a duration prescribed in a protocol.

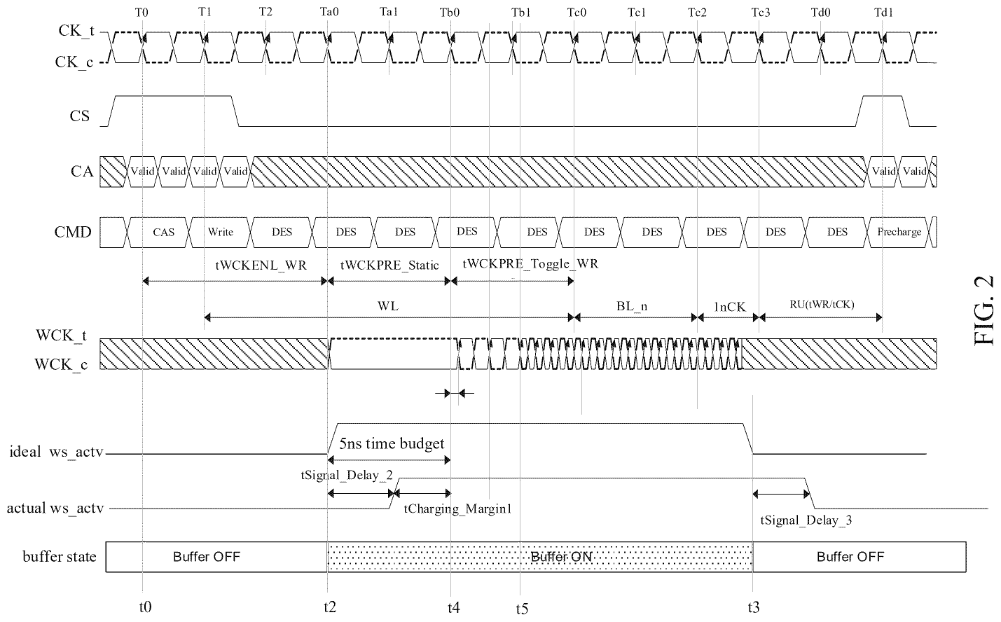

It is to be noted that FIG. 2 schematically shows the timing for performing a write operation, wherein the second duration tWCKENL may also be denoted as tWCKENL_WR, and the time instant when the command address signal CAS CMD is received is the initial time instant t0.

The clock generation circuit 104 may be pre-charged within a fourth duration tWCKPRE_Static based on the second control signal, wherein the fourth duration tWCKPRE_Static is a duration from the second time instant t2 to a fourth time instant t4 after the second time instant t2, which may be interpreted as a duration after the second duration tWCKENL has elapsed after the command address signal is received, but before a time instant of first clock signal triggering (which may also be referred to as a time instant when a second clock signal is generated based on the first clock signal, i.e., the fourth time instant t4).

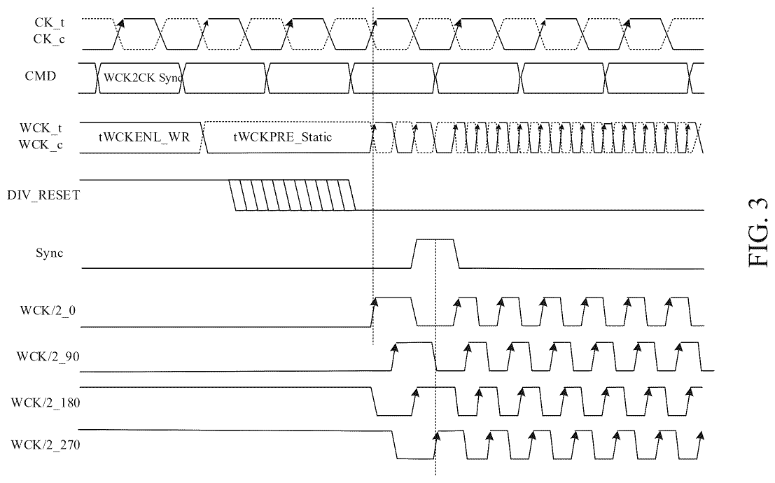

The clock generation circuit 104 may generate the second clock signal based on the first clock signal at a time instant after the second duration tWCKENL and the fourth duration tWCKPRE_Static have elapsed, i.e., the fourth time instant t4. For example, a synchronization operation from the first clock signal to a clock signal is performed based on a clock synchronization signal command WCK2CK Sync CMD, and the second clock signal is generated based on the first clock signal after the synchronization operation. The clock signal may be a pair of differential clock signals CK_t and CK_c, and the first clock signal may be a pair of differential clock signals WCK_t and WCK_c, while the second clock signal may be clock signals of four phases WCK/2_0, WCK/2_90, WCK/2_180, and WCK/2_270 (as shown in FIG. 3).

The clock generation circuit may stop outputting the second clock signal at a third time instant t3 after the second clock signal is generated. In some examples, the pre-charging time of the clock generation circuit is limited by process corners and design structures, and in order to guarantee a charging time to meet a regulatory requirement, the pre-charging of an input buffer of the clock generation circuit and a frequency divider of the clock generation circuit are simultaneously reset at the third time instant t3, and the enabling of the clock generation circuit ends at the third time instant t3, which may lead to relatively-low quality of the second clock signal, and the pre-charging delay of the input buffer reduces the data transmission efficiency of the memory device.

It is to be noted that, referring to FIG. 2, an ideal second control signal ideal ws_actv triggers the enabling at the second time instant t2, and finishes the enabling at the third time instant t3, wherein the second time instant t2 corresponds to a time instant of triggering the enabling of the clock generation circuit 104 (for example, a time instant when an input buffer state of the clock generation circuit 104 becomes on (Buffer ON)), and the third time instant t3 corresponds to a time instant of finishing the enabling of the clock generation circuit 104 (for example, a time instant when the input buffer state of the clock generation circuit 104 becomes off (Buffer OFF)). Referring to FIG. 2, an actual second control signal actual ws_actv triggers the enabling at a time instant after a second signal delay tSignal_Delay_2 has elapsed after the second time instant t2, and finishes the enabling at a time instant after a third signal delay tSignal_Delay_3 has elapsed after the third time instant t3.

Referring to FIGS. 2 and 3, the enabling of the clock generation circuit needs to be ready after the second duration tWCKENL has elapsed after the command address signal CAS CMD is received, but before the time instant of first clock signal triggering. In an example, an input buffer of the clock generation circuit needs to be turned on after the second duration tWCKENL has elapsed after the command address signal CAS CMD is received, and be ready before the time instant of first clock signal triggering, that is, the input buffer of the clock generation circuit needs to be turned on at a time instant after the second time instant t2, and be ready before the fourth time instant t4. Herein, being ready may be interpreted to include the completion of the pre-charging and enabling operations.

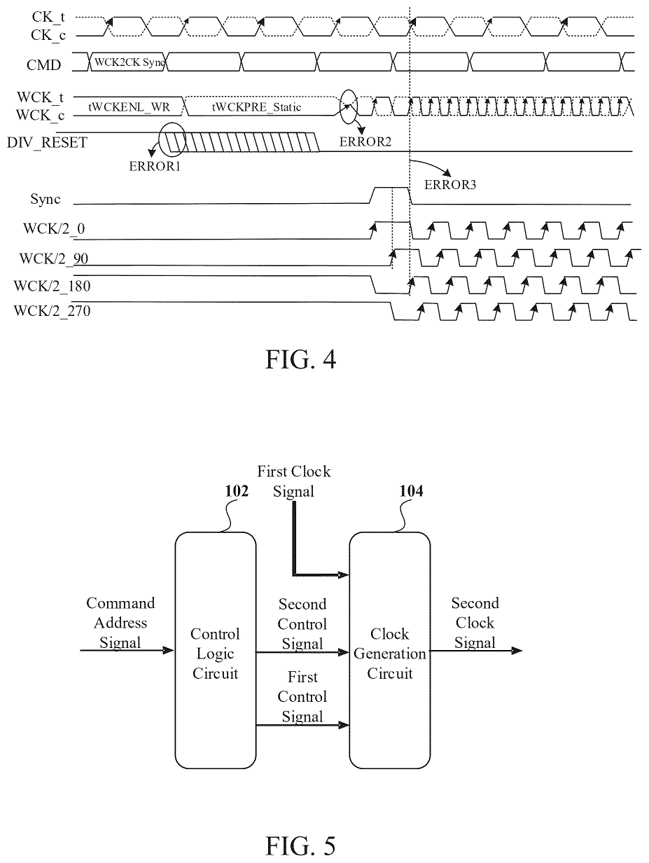

Referring to FIG. 4, the early or delayed turning-on of the input buffer of the clock generation circuit may lead to an initial state error in the frequency divider (which may be configured to receive a frequency division reset signal DIV_RESET) of the clock generation circuit. Referring to a first error ERROR1 shown in FIG. 4, the early turning-on of the input buffer of the clock generation circuit may cause the frequency divider to turn on during an invalid first clock signal. Referring to a second error ERROR2 shown in FIG. 4, the delayed turning-on of the input buffer of the clock generation circuit may cause a first pulse of the first clock signal to disappear, which in turn causes the synchronization operation (which may be performed based on receiving of a synchronization signal Sync) from the first clock signal to the clock signal to be unaligned (a third error ERROR3 shown in FIG. 4).

Referring back to FIGS. 2 and 3, the pre-charging time of the clock generation circuit is limited by a duration determined by the fourth duration tWCKPRE_Static minus the second signal delay tSignal_Delay_2, that is, the pre-charging time of the clock generation circuit is limited by a first pre-charging margin tCharging_Margin1 of the clock generation circuit, wherein the second signal delay tSignal_Delay_2 is a signal delay caused by a circuit that generates the second control signal itself. In some examples, a time budget of the fourth duration tWCKPRE_Static may be 5 ns. For example, referring to FIG. 2, the input buffer of the clock generation circuit needs to be turned on at a time instant after the second time instant t2, and be ready before the fourth time instant t4, that is, it needs to be ready within the fourth duration tWCKPRE_Static. In order to guarantee a charging time to meet a regulatory requirement for guaranteeing the data transmission efficiency, a to-be-ready time for the clock generation circuit should not be too long, which requires that the fourth duration tWCKPRE_Static should not be set too large (e.g., less than or equal to 5 ns). Since both the pre-charging and the enabling of the clock generation circuit may be controlled by the second control signal ws_actv, the clock generation circuit 104 needs to be pre-charged within the fourth duration tWCKPRE_Static, and the pre-charging of the clock generation circuit also needs to be longer than a certain time in order to provide enough pre-charging time, which also requires that the fourth duration tWCKPRE_Static should not be set too small (e.g., greater than 5 ns). Therefore, the first pre-charging margin tCharging_Margin1 of the clock generation circuit is relatively limited, and should not be too long or too short. For example, referring to FIG. 2, if the first pre-charging margin tCharging_Margin1 of the clock generation circuit is small, the enough pre-charging time is unable to be provided, resulting in a worse duty cycle of the input buffer of the clock generation circuit, and the pre-charging speed of the input buffer of the clock generation circuit being limited, thus reducing the data transmission efficiency of the memory device. If the first pre-charging margin tCharging_Margin1 of the clock generation circuit is large, however, the data transmission efficiency is also reduced.

In view of this, examples of the present disclosure provide a memory device and an operation method thereof.

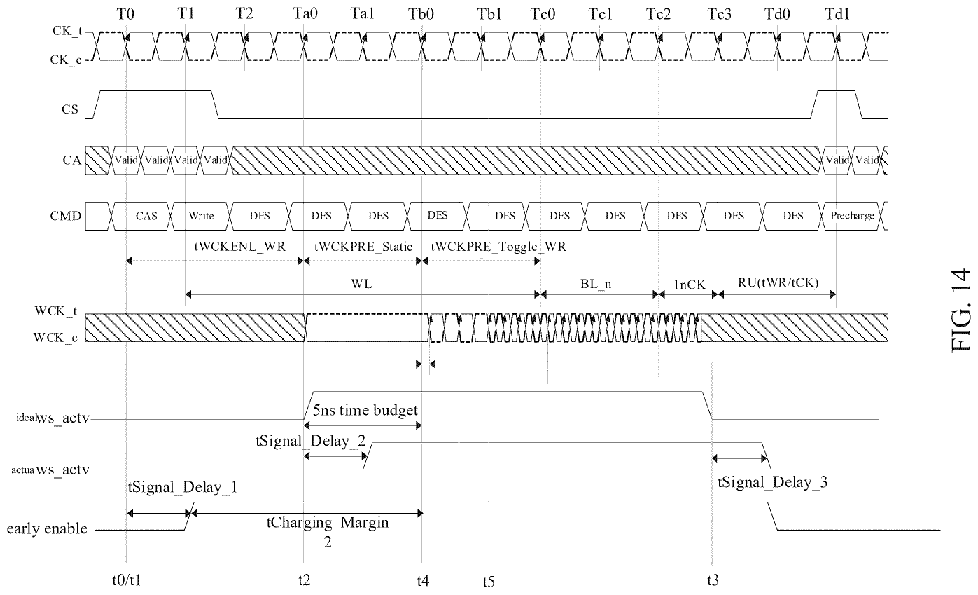

In a first aspect, examples of the present disclosure provide a memory device. Referring to FIGS. 5 and 14, the memory device comprises: a memory cell array; a control logic circuit coupled with the memory cell array and configured to: receive a command address signal, output a first control signal at a first time instant, and output a second control signal at a second time instant, wherein the first time instant is different from the second time instant; and a clock generation circuit configured to: receive a first clock signal, the first control signal and the second control signal, be pre-charged according to the first control signal, perform frequency division processing on the first clock signal according to the second control signal to output a second clock signal, wherein the first clock signal is different from the second clock signal.

In some examples, the memory device comprises Dynamic Random-Access Memory (DRAM), Synchronous Dynamic Random-Access Memory (SDRAM), Double-Data-Rate Fourth Generation SDRAM (DDR4 SDRAM), or Low Power Double-Data-Rate Fifth Generation SDRAM (LPDDR5 SDRAM).

The memory device comprises a memory cell array, and a peripheral circuit coupled with the memory cell array.

The memory cell array may comprise a plurality of memory banks, for example, 8 memory banks, however the number of memory banks may be less than 8 or greater than 8. Each memory bank may comprise a plurality of memory arrays, for example, 4 memory arrays, however the number of memory arrays may be less than 4 or greater than 4. In an example, the DRAM comprising 4 memory arrays per memory bank may be denoted as X4 DRAM. Each memory cell (also referred to as a storage element) in the memory cell array may be a 1T1C architecture formed by one array transistor and one capacitance, and both the capacitor and the array transistor are generally based on metal-oxide-semiconductor (MOS) technology. The capacitor may be charged or discharged, and two states of being charged and being discharged of the capacitor may be used to represent two values of a bit, which are conventionally referred to as one and zero. The capacitor may be formed in a plane configuration, a stack configuration, or a trench configuration, depending on a manufacturing method. The capacitor may be coupled to a first doping region (e.g., a source region) of the array transistor, so as to be charged or discharged through the first doping region. A word line may be coupled to a gate of the array transistor, so as to turn on or turn off the array transistor. A bit line may be coupled to a second doping region (e.g., a drain region) of the array transistor, and act as a path for charging or discharging the capacitor.

The peripheral circuit may be coupled to the memory cell array through the bit lines and the word lines. The peripheral circuit may comprise any suitable analog, digital, and hybrid signal circuits for facilitating operations of the memory cell array by applying voltage signals and/or current signals to each of target memory cells and sensing voltage signals and/or current signals from each of target memory cells via the bit lines and the word lines. The peripheral circuit may comprise various types of peripheral circuits formed using the MOS technology. The peripheral circuit may comprise a plurality of peripheral transistors to form a circuit that is configured to perform operations on the memory cell array (e.g., writing or reading storage elements of the memory cell array).

The peripheral circuit comprises a control logic circuit 102 and a clock generation circuit 104. The control logic circuit 102 may control operations of the memory device. For example, the control logic circuit may generate a control signal for the memory device, so as to perform a write operation or a read operation. The control logic circuit 102 may generate a first control signal and a second control signal for controlling the clock generation circuit 104. The clock generation circuit 104 may generate a second clock signal (which may also be referred to as an output clock signal OCLK) based on a first clock signal (which may also be referred to as a write clock signal WCK herein). The clock generation circuit 104 may be pre-charged according to the first control signal, and perform frequency division processing on the first clock signal according to the second control signal, and output the second clock signal.

The peripheral circuit may further comprise a sense amplifier, a word line driver, a column decoder, a row decoder, a data input/output (I/O) buffer, and etc. The sense amplifier is configured to sense a low power signal that is from a bit line and that represents a data bit (one or zero) stored in a memory cell, and amplify a small voltage swing to a recognizable logic level, so that a logic unit outside the memory device may interpret the data correctly. The word line driver may be configured to select/unselect a memory block of the memory cell array, and to select/unselect a word line of the memory array of the memory bank. The column decoder is coupled to the bit lines of the memory arrays of the memory banks of the memory device, and is configured to read or write the memory cells of the memory device. The row decoder is coupled to the word lines of the memory cells of the memory device, and is configured to turn on or turn off the gates of the transistors. The input/output buffer is configured to, according to an input/output signal, write a data signal to the memory device or output the same to the external of the memory device.

The memory device may receive a clock signal CK, a command signal CMD, and an address signal ADDR. A clock buffer of the memory device may receive the clock signal CK, generate an internal clock signal ICK by buffering the clock signal CK, and provide the internal clock signal ICK to a circuit of the memory device that is configured to process the command signal CMD and the address signal ADDR.

The memory device may receive a write clock signal WCK and a data signal DQ. The clock generation circuit of the memory device may receive the write clock signal WCK, and when performing the write operation or the read operation, the clock generation circuit generates an output clock signal OCLK based on the write clock signal WCK, and a data I/O buffer of the memory device may write the data signal DQ to the memory device or output the same to the external of the memory device, based on the output clock signal OCLK. For example, the clock generation circuit may receive the write clock signal WCK comprising a pair of differential clock signals, and generate a third clock signal and a fourth clock signal having a phase difference of 90 degrees relative to each other, wherein the third clock signal and the fourth clock signal may be used as the output clock signal OCLK and a strobe signal DQS and provided to the data I/O buffer, and the data I/O buffer writes the data signal DQ to the memory device or output the same to the external of the memory device, based on the output clock signal OCLK and the strobe signal DQS.

In some examples, the peripheral circuit may further comprise an error checking and correcting (ECC) engine. For example, in the write operation of the memory device, the data I/O buffer may convert the data signal DQ into data DTA and provide the same to the ECC engine; and in the read operation of the memory device, the data I/O buffer may convert the data DTA from the ECC engine into the data signal DQ based on the output clock signal OCLK from the clock generation circuit, and output the data signal DQ and the strobe signal DQS to the external of the memory device. In some examples, the control logic circuit may generate a third control signal for controlling the ECC engine.

It is to be noted that FIG. 14 schematically shows the timing for performing a write operation, wherein the second duration tWCKENL may also be denoted as tWCKENL_WR, and the time instant when the command address signal CAS CMD is received is the initial time instant t0. For example, the memory device is configured so that, during the execution of the write operation, the control logic circuit 102 receives a chip select signal CS, a command address signal CA and a command signal CMD, and triggers a Column Address Strobe (CAS) signal at the initial time instant t0. Here and below, the command address signal received by the control logic circuit 102 at the initial time instant t0 is denoted as a command address signal CAS CMD.

The clock generation circuit 104 of the memory device may be triggered by the command address signal CAS CMD received by the control logic circuit 102 of the memory device, and the pre-charging and the enabling of the clock generation circuit 104 may be controlled respectively by the first control signal and the second control signal. After a first duration tWCKPRE has elapsed after the command address signal is received by the memory device, the clock generation circuit is pre-charged, and after the second duration tWCKENL has elapsed after the command address signal is received by the memory device, the clock generation circuit may be enabled based on the second control signal, wherein the first duration tWCKPRE is a duration from the time instant when the command address signal is received to the first time instant, the second duration tWCKENL is a duration from the time instant when the command address signal is received to the second time instant, and the second duration tWCKENL is a duration prescribed in a protocol.

In some examples, the enabling of the clock generation circuit 104 needs to be ready within the fourth duration tWCKPRE_Static, and the fourth duration tWCKPRE_Static is a duration from the second time instant t2 to the fourth time instant t4 after the second time instant t2. In an example, the input buffer of the clock generation circuit needs to be turned on after the second duration tWCKENL has elapsed after the command address signal is received, and be ready before the time instant of first clock signal triggering.

In the examples of the present disclosure, the pre-charging and the enabling of the clock generation circuit of the memory device can be controlled respectively by the first control signal and the second control signal generated by the control logic circuit of the memory device, such that the limitation that the clock generation circuit has a shorter pre-charging duration is mitigated, and the output of the clock generation circuit has enough time to stabilize, thereby reducing pre-charging delay. The clock generation circuit can provide a better duty cycle for the first clock signal. When receiving an active signal, the clock generation circuit is faster to respond, and the pre-charging duration of the clock generation circuit is no longer limited by the enabling duration of the clock generation circuit, thereby improving the data transmission efficiency of the memory device.

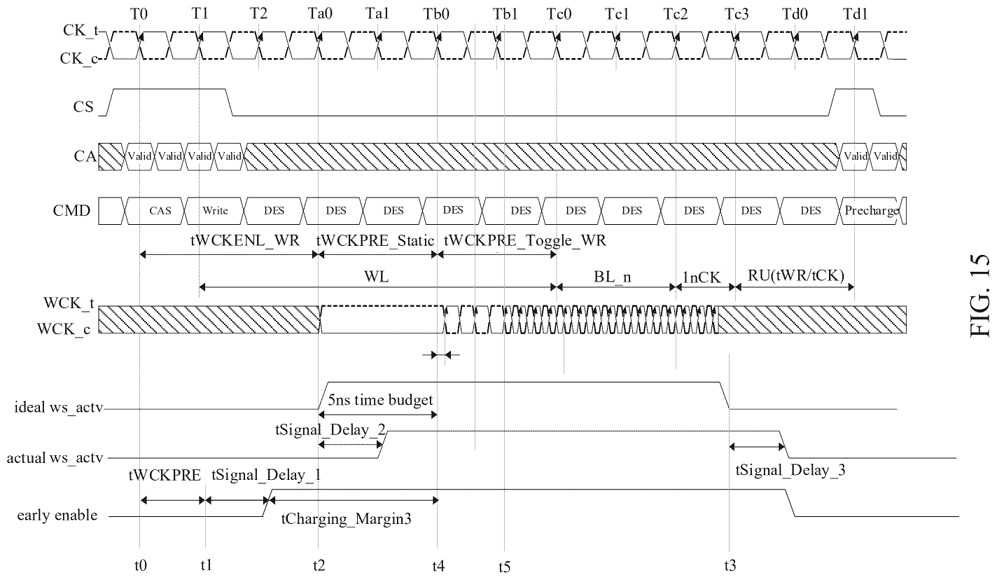

Referring to FIGS. 5 and 14, or FIGS. 5 and 15, in some examples, the first time instant comprises a time instant when the command address signal is received or a time instant thereafter; and the first time instant is earlier than the second time instant. That is to say, the clock generation circuit may be pre-charged at any time instant within the second duration tWCKENL.

Referring to FIGS. 5 and 15, in some examples, at a time instant after the command address signal is received, the control logic circuit outputs the first control signal according to the command address signal CAS CMD (a situation where the first duration tWCKPRE is greater than zero and less than the second duration tWCKENL), that is to say, the control logic circuit starts to pre-charge the clock generation circuit after the first duration tWCKPRE and a first signal delay tSignal_Delay_1 have elapsed after the time instant when the command address signal is received. It is to be noted that, the control logic circuit starts to pre-charge the clock generation circuit after the first signal delay tSignal_Delay_1 has elapsed after the time instant when the command address signal is received, wherein the first signal delay tSignal_Delay_1 may be interpreted as the delay caused by the generation of the first control signal by the control logic circuit according to the command address signal CAS CMD, i.e., a duration from the time instant when the command address signal is received by the control logic circuit to the time instant when the first control signal is generated. Compared to the first pre-charging margin tCharging_Margin1 of the clock generation circuit of FIG. 2, in the examples of the present disclosure, a third pre-charging margin tCharging_Margin3 of the clock generation circuit is larger, and the pre-charging duration of the clock generation circuit may be longer, such that the output of the clock generation circuit has enough time to stabilize, and the quality of the first clock signal received can be improved, thereby reducing pre-charging delay.

Referring to FIGS. 5 and 14, in some examples, at the time instant when the command address signal is received, the control logic circuit outputs the first control signal according to the command address signal CAS CMD (a situation where the first duration tWCKPRE is zero), wherein the first control signal is to start pre-charging the clock generation circuit. Compared to the first pre-charging margin tCharging_Margin1 of the clock generation circuit of FIG. 2, in the examples of the present disclosure, a second pre-charging margin tCharging_Margin2 of the clock generation circuit is larger, and the pre-charging duration of the clock generation circuit may be longer, such that the output of the clock generation circuit has enough time to stabilize, and the quality of the first clock signal received can be improved, thereby reducing pre-charging delay.

In the examples of the present disclosure, the pre-charging and the enabling of the clock generation circuit of the memory device may be controlled respectively by the first control signal and the second control signal generated by the control logic circuit of the memory device, wherein the first time instant is earlier than the second time instant, such that the pre-charging duration of the clock generation circuit may be longer, the output of the clock generation circuit has enough time to stabilize, and the quality of the first clock signal received can be improved, thereby reducing pre-charging delay. The clock generation circuit can provide a better duty cycle for the first clock signal. When receiving an active signal, the clock generation circuit is faster to respond, and the pre-charging duration of the clock generation circuit is no longer limited within the fourth duration, and the enabling duration of the clock generation circuit may be reduced, that is, the fourth duration may be reduced, thereby improving the data transmission efficiency.

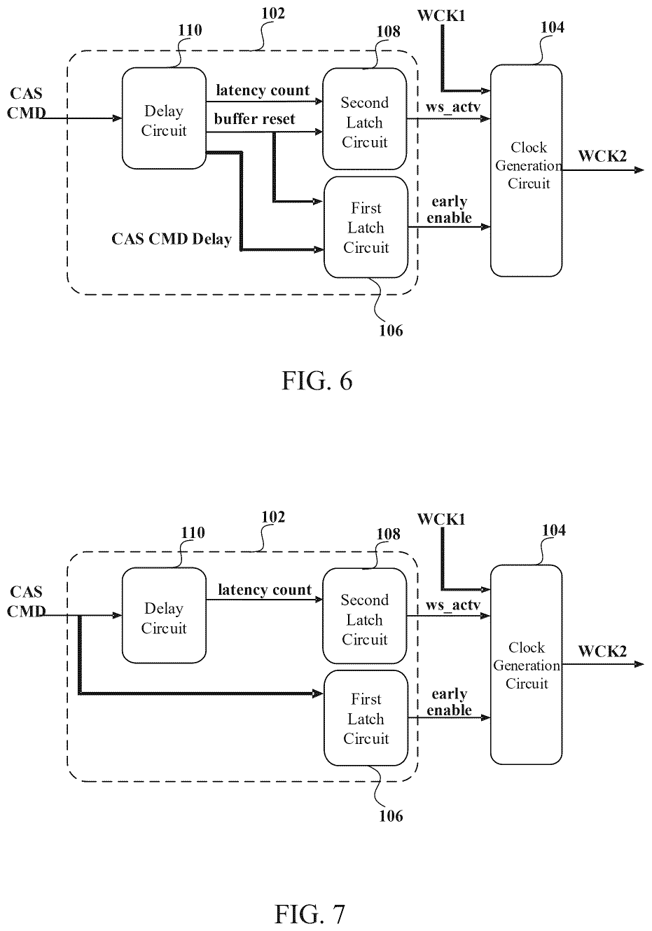

Referring to FIGS. 6 and 15, in some examples, the control logic circuit 102 comprises: a delay circuit 110 configured to receive the command address signal CAS CMD, output a delayed signal CAS CMD Delay of the command address signal at a first time instant, and output a latency count signal latency count at a second time instant; a first latch circuit 106 configured to receive the delayed signal CAS CMD Delay of the command address signal, and output the first control signal early enable; and a second latch circuit 108 configured to receive the latency count signal latency count, and output the second control signal ws_actv. For example, the delayed signal CAS CMD Delay of the command address signal is received at a time instant after the first duration tWCKPRE (the situation where the first duration tWCKPRE is greater than zero and less than the second duration tWCKENL) has elapsed after the initial time instant t0, and the first control signal early enable is outputted at a time instant after the first signal delay tSignal_Delay_1 has elapsed after the delayed signal CAS CMD Delay of the command address signal is received.

Referring to FIG. 7, in some examples, the control logic circuit 102 comprises: a first latch circuit 106 configured to receive the command address signal CAS CMD, and output the first control signal early enable at a first time instant; a delay circuit 110 configured to receive the command address signal CAS CMD, and output the latency count signal latency count at a second time instant; and a second latch circuit 108 configured to receive the latency count signal latency count, and output the second control signal ws_actv.

Referring to FIGS. 7 and 14, in some examples, the first latch circuit 106 is configured such that the first control signal early enable outputted at the first time instant t1 starts to be in a first logic state; and according to the first control signal early enable starting to be in the first logic state, the clock generation circuit 104 starts to be pre-charged; the second latch circuit 108 is configured such that the second control signal ws_actv outputted at the second time instant t2 starts to be in an activated state; and according to the second control signal ws_actv starting to be in the activated state, the clock generation circuit 104 starts to receive the first clock signal WCK1 and output the second clock signal WCK2.

In the examples of the present disclosure, logic states of signals may be expressed as a logic state “0” and a logic state “1”. The logic state “0” and the logic state “1” are indicated respectively as a logic low level and a logic high level, or indicated respectively as a logic high level and a logic low level. Here and below, descriptions are made by using a second logic state and a first logic state of a signal being respectively indicated as a logic low level and a logic high level and using a non-activated state and an activated state of the signal being respectively indicated as a logic low level and a logic high level as examples.

It is to be noted that, the first control signal early enable outputted by the first latch circuit 106 after the first signal delay tSignal_Delay_1 has elapsed after the first time instant t1 when the command address signal CAS CMD is received starts to be in the first logic state. The second control signal ws_actv outputted by the second latch circuit 108 after the second signal delay tSignal_Delay_2 has elapsed after the second time instant t2 when the latency count signal latency count is received starts to be in the activated state, wherein the second signal delay tSignal_Delay_2 may be interpreted as the delay caused by the generation of the second control signal by the second latch circuit 108 according to the latency count signal latency count, i.e., a duration from the time instant when the latency count signal latency count is received by the second latch circuit 108 to the time instant when the second control signal is generated.

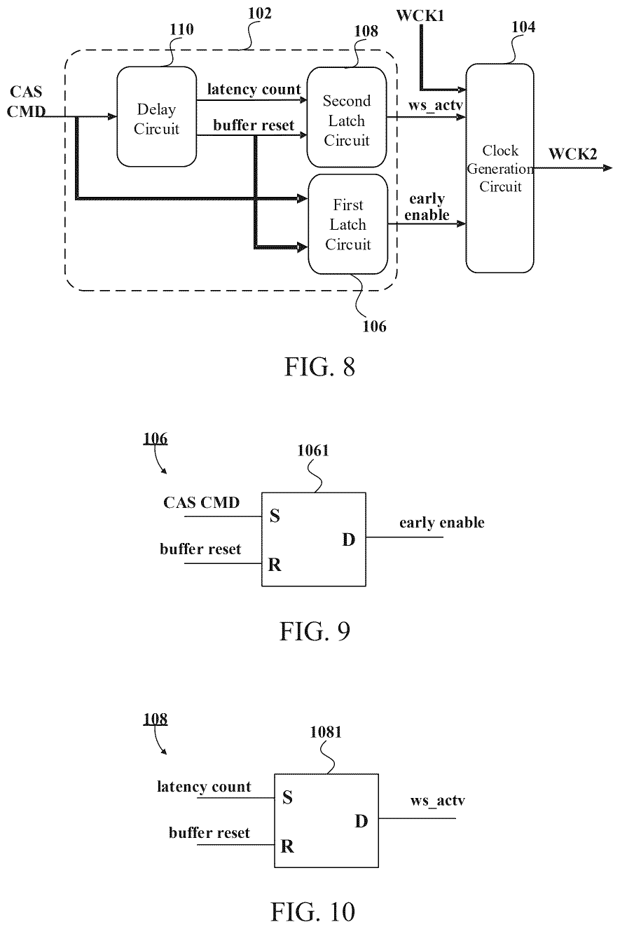

Referring to FIGS. 6 and 15, or FIGS. 8 and 14, in some examples, the delay circuit 110 is further configured to receive the command address signal CAS CMD, and output a reset signal buffer reset at a third time instant t3, wherein the third time instant t3 is later than the second time instant t2; the first latch circuit 106 is further configured to receive the reset signal buffer reset, and switch the first control signal early enable outputted at the third time instant t3 to be in the second logic state; and according to the first control signal early enable starting to be in the second logic state, the clock generation circuit 104 finishes being pre-charged; the second latch circuit 108 is further configured to receive the reset signal buffer reset, and switch the second control signal ws_actv outputted at the third time instant t3 to be in the non-activated state; and according to the second control signal ws_actv being in the non-activated state, the clock generation circuit 104 stops outputting the second clock signal WCK2.

In the examples of the present disclosure, the duration from the time instant when the reset signal buffer reset is received by the first latch circuit 106 to the time instant when the first control signal is generated is the same as the duration from the time instant when the reset signal buffer reset is received by the second latch circuit 108 to the time instant when the second control signal is generated.

It is to be noted that, the first latch circuit 106 finishes the pre-charging after a third signal delay tSignal_Delay_3 has elapsed after the third time instant t3 when the reset signal buffer reset is received, wherein the third signal delay tSignal_Delay_3 may be interpreted as the delay caused by the generation of the first control signal by the first latch circuit 106 according to the reset signal buffer reset, i.e., the duration from the time instant when the reset signal buffer reset is received by the first latch circuit 106 to the time instant when the first control signal is generated. The second latch circuit 108 stops the outputting of the second clock signal WCK2 after the third signal delay tSignal_Delay_3 has elapsed after the third time instant t3 when the reset signal buffer reset is received, wherein the third signal delay tSignal_Delay_3 may be interpreted as the delay caused by the generation of the second control signal by the second latch circuit 108 according to the reset signal buffer reset, i.e., the duration from the time instant when the reset signal buffer reset is received by the second latch circuit 108 to the time instant when the second control signal is generated.

In some examples, the first latch circuit 106 and the second latch circuit 108 may be constituted by same or similar logic devices, and signal latency caused by constructing the first latch circuit 106 itself for generating the first control signal is the same as signal latency caused by constructing the second latch circuit 108 itself for generating the second control signal.

Referring to FIGS. 9 and 10, in some examples, the first latch circuit 106 comprises a first RS latch 1061, the first RS latch 1061 having a reset terminal R to receive the reset signal buffer reset, a set terminal S to receive the command address signal CAS CMD, and an output terminal D to output the first control signal early enable; and/or the second latch circuit 108 comprises a second RS latch 1081, the second RS latch 1081 having a reset terminal R to receive the reset signal buffer reset, a set terminal S to receive the latency count signal latency count, and an output terminal D to output the second control signal ws_actv.

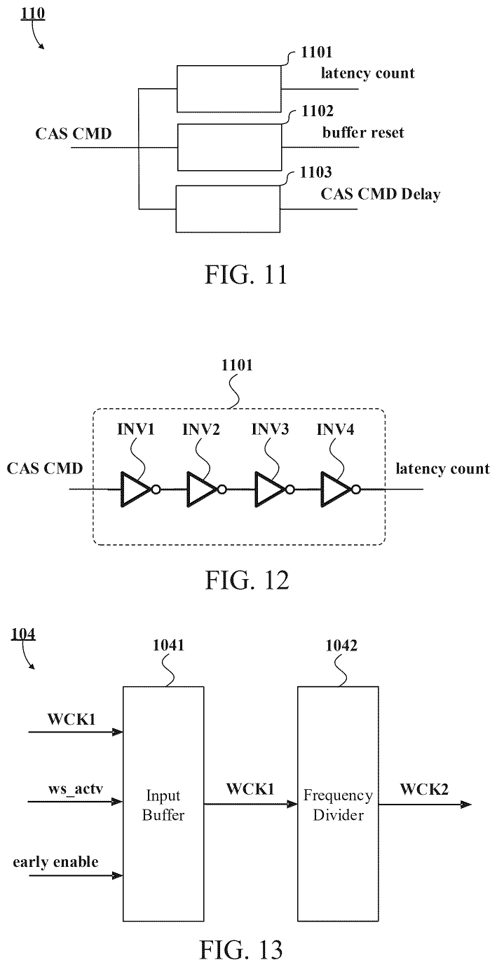

Referring to FIGS. 8 and 11 (a third clock delay unit 1103 of FIG. 11 is omitted here for ease of understanding), in some examples, the delay circuit 110 comprises: a first clock delay unit 1101 configured to receive the command address signal CAS CMD, and output the latency count signal latency count after a first preset duration; and a second clock delay unit 1102 configured to receive the command address signal CAS CMD, and output the reset signal buffer reset after a second preset duration, wherein the first preset duration is a difference between the second time instant t2 and the time instant when the command address signal is received (i.e., the initial time instant t0), and the second preset duration is a difference between the third time instant t3 and the time instant when the command address signal is received (i.e., the initial time instant t0).

In some examples, the delay circuit 110 may provide delay with different durations. For example, the delay with different durations may be set according to different configurations, and herein, the configurations may include clock frequencies, user settings, etc.; and under a certain configuration, for example, the delay is fixed at a certain clock frequency or a certain user setting.

In some examples, the first clock delay unit 1101 and the second clock delay unit 1102 may have the same or similar circuit structure. The first clock delay unit 1101 and the second clock delay unit 1102 may be constituted by a same plurality of logic devices, for example, the delay of each logic device is one delay unit, and the delay of the first clock delay unit 1101 and the second clock delay unit 1102 may be a multiple of delay units. In this way, the first clock delay unit 1101 with the delay being the first preset duration, and the second clock delay unit 1102 with the delay being the second preset duration may be constructed according to the delay of each of the logic devices and data of the logic devices. In an example, referring to FIG. 12, the first clock delay unit 1101 may be composed of four NOT gates INV1, INV2, INV3 and INV4 connected in series, wherein the delay of each NOT gate is one NOT gate delay unit, therefore the delay of the first clock delay unit 1101 may be four NOT gate delay units, and the four NOT gate delay units constitute the first preset duration.

Referring to FIGS. 6 and 11, in some examples, the delay circuit 110 further comprises: a third clock delay unit 1103 configured to receive the command address signal CAS CMD, and output a delayed signal CAS CMD Delay of the command address signal after a third preset duration, wherein the third preset duration is a difference between the first time instant t1 and the time instant when the command address signal is received (i.e., the initial time instant t0).

In some examples, the example structure of the third clock delay unit 1103 may be understood by referring to the circuit structure of the first clock delay unit 1101 or the second clock delay unit 1102.

Referring to FIG. 13, in some examples, the clock generation circuit 104 comprises: an input buffer 1041 configured to receive the first clock signal WCK1, the first control signal early enable and the second control signal ws_actv, start to be pre-charged according to the first control signal early enable, and start to transmit the first clock signal WCK1 according to the second control signal ws_actv; and a frequency divider 1042 configured to receive the first clock signal WCK1 transmitted by the input buffer, perform frequency division processing on the received first clock signal WCK1 transmitted by the input buffer to output the second clock signal WCK2.

In some examples, the first clock signal WCK1 comprises a pair of differential clock signals WCK_t and WCK_c; the second clock signal WCK2 comprises clock signals of four phases with a phase difference of 90 degrees in sequence; and the frequency divider 1042 is configured to perform frequency division on the pair of differential clock signals WCK_t and WCK_c to output the clock signals of four phases, wherein the clock signals of four phases comprise a third clock signal WCK/2_0 and a third complementary clock signal WCK/2_180 having a phase difference of 180 degrees relative to each other, and a fourth clock signal WCK/2_90 and a fourth complementary clock signal WCK/2_270 having a phase difference of 180 degrees relative to each other, wherein the third clock signal WCK/2_0 and the fourth clock signal WCK/2_90 have a phase difference of 90 degrees relative to each other; wherein two signals having a phase difference of 90 degrees from among the third clock signal WCK/2_0, the third complementary clock signal WCK/2_180, the fourth clock signal WCK/2_90 and the fourth complementary clock signal WCK/2_270 are used to output data from the memory cell array.

Herein, the clock signals of four phases with the phase difference of 90 degrees in sequence may be understood with reference to the clock signals of four phases WCK/2_0, WCK/2_90, WCK/2_180, and WCK/2_270 shown in FIG. 3.

In some examples, the two signals (e.g., the third clock signal WCK/2_0 and the fourth clock signal WCK/2_90) having a phase difference of 90 degrees from among the third clock signal WCK/2_0, the third complementary clock signal WCK/2_180, the fourth clock signal WCK/2_90, and the fourth complementary clock signal WCK/2_270 may be used as the output clock signal OCLK and the strobe signal DQS and provided to the data I/O buffer, and the data I/O buffer writes the data signal DQ to the memory device or output the same to the external of the memory device, based on the output clock signal OCLK and the strobe signal DQS.

In some examples, the clock generation circuit 104 further comprises: a synchronization detector configured to receive the two signals, and output a detection signal according to the phase difference between the two signals, wherein the detection signal is to represent whether or not the two signals have a phase difference of 90 degrees relative to each other.

In some examples, the synchronization detector is configured to, in response to a synchronization detection signal Sync (referring to FIG. 3), receive the two signals and output the detection signal. In an example, the synchronization detection signal Sync may be in an activated state within a duration from a time instant when the second clock signal WCK2 is outputted (referring to the fifth time instant t5 of FIG. 14) to a time instant when the second clock signal WCK2 stops being outputted (referring to the third time instant t3 of FIG. 14), for receiving the two signals and outputting the detection signal.

In some examples, any one of the memory devices in the above-discussed respective examples comprises a dynamic random access memory.

In a second aspect, examples of the present disclosure provide another memory device. Referring to FIGS. 7 and 14, the memory device comprises: a first latch circuit having a first input terminal to receive a command address signal, and an output terminal to output a first control signal at a first time instant; a delay circuit having an input terminal to receive the command address signal, and a first output terminal to output a latency count signal at a second time instant, wherein the first time instant is different from the second time instant; a second latch circuit having a first input terminal connected to the first output terminal of the delay circuit to receive the latency count signal, and an output terminal to output a second control signal at the second time instant; and a clock generation circuit having a first input terminal to receive a first clock signal, a second input terminal connected to the output terminal of the first latch circuit to receive the first control signal, a third input terminal connected to the output terminal of the second latch circuit to receive the second control signal, and an output terminal to output a second clock signal, wherein the first control signal is to indicate a start of pre-charging, the second control signal is to indicate a start of frequency division processing on the first clock signal, and the first clock signal is different from the second clock signal.

In some examples, the first control signal outputted by the output terminal of the first latch circuit at the first time instant starts to be in a first logic state, and the clock generation circuit receives, at the second input terminal of the clock generation circuit, the first control signal starting to be in the first logic state, and starts to be pre-charged; and the second control signal outputted by the output terminal of the second latch circuit at the second time instant starts to be in an activated state, and the clock generation circuit receives, at the third input terminal of the clock generation circuit, the second control signal starting to be in the activated state, receives the first clock signal at the first input terminal of the clock generation circuit, and outputs the second clock signal at the output terminal of the clock generation circuit.

Referring to FIGS. 8 and 14, in some examples, a second output terminal of the delay circuit outputs a reset signal at a third time instant, wherein the third time instant is later than the second time instant; a second input terminal of the first latch circuit is connected to the second output terminal of the delay circuit to receive the reset signal, and the first control signal outputted by the output terminal of the first latch circuit at the third time instant is switched to be in a second logic state, and the clock generation circuit receives, at the second input terminal of the clock generation circuit, the first control signal starting to be in the second logic state and finishes being pre-charged; and a second input terminal of the second latch circuit is connected to the second output terminal of the delay circuit to receive the reset signal, and the second control signal outputted by the output terminal of the second latch circuit at the third time instant is switched to be in a non-activated state, and the clock generation circuit receives, at the third input terminal of the clock generation circuit, the second control signal being in the non-activated state and stops outputting the second clock signal.

Referring to FIGS. 9 and 10, in some examples, the first latch circuit comprises a first RS latch, the first RS latch having a reset terminal to receive the reset signal, a set terminal to receive the command address signal, and an output terminal to output the first control signal; and/or the second latch circuit comprises a second RS latch, the second RS latch having a reset terminal to receive the reset signal, a set terminal to receive the latency count signal, and an output terminal to output the second control signal.

Referring to FIGS. 11 and 12, in some examples, the delay circuit comprises: a first clock delay unit having an input terminal to receive the command address signal, and an output terminal to output the latency count signal after a first preset duration; and a second clock delay unit having an input terminal to receive the command address signal, and an output terminal to output the reset signal after a second preset duration, wherein the first preset duration is a difference between the second time instant and the time instant when the command address signal is received, and the second preset duration is a difference between the third time instant and the time instant when the command address signal is received.

Referring to FIG. 13, in some examples, the clock generation circuit comprises: an input buffer having a first input terminal to receive the first clock signal, a second input terminal connected to the output terminal of the first latch circuit to receive the first control signal, a third input terminal connected to the output terminal of the second latch circuit to receive the second control signal, and an output terminal to transmit the first clock signal; and a frequency divider having an input terminal connected to the output terminal of the input buffer to receive the first clock signal transmitted by the input buffer, and an output terminal to output the second clock signal, wherein the first clock signal comprises a pair of differential clock signals, the second clock signal comprises clock signals of four phases with a phase difference of 90 degrees in sequence, and two signals having a phase difference of 90 degrees from among the clock signals of four phases are for outputting data from a memory cell array.

In the examples of the present disclosure, the pre-charging and the enabling of the clock generation circuit of the memory device can be controlled respectively by the first control signal and the second control signal generated by the control logic circuit of the memory device, such that the limitation that the clock generation circuit has a shorter pre-charging duration is mitigated, and the output of the clock generation circuit has enough time to stabilize, thereby reducing pre-charging delay. The clock generation circuit can provide a better duty cycle for the first clock signal. When receiving an active signal, the clock generation circuit is faster to respond, and the pre-charging duration of the clock generation circuit is no longer limited by the enabling duration of the clock generation circuit, thereby improving the data transmission efficiency.

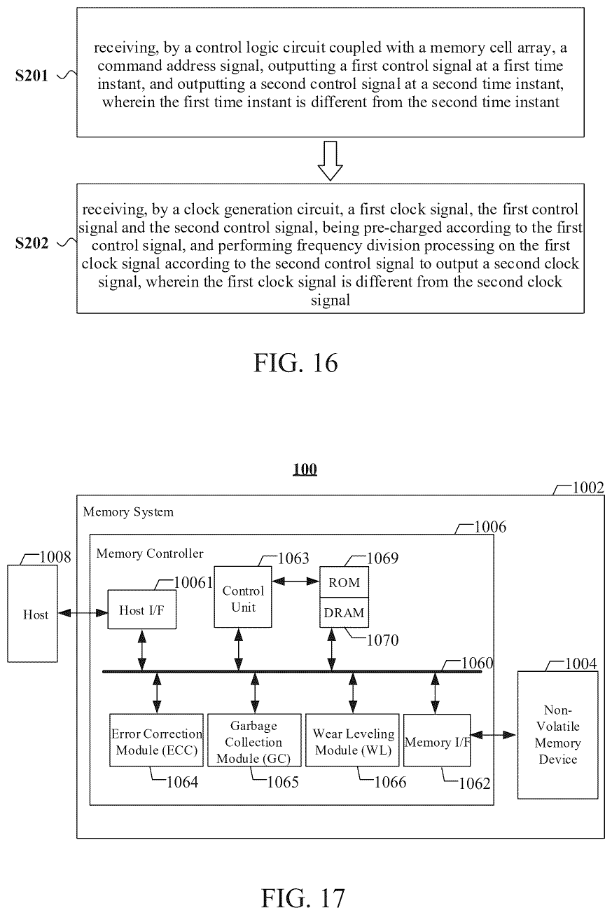

In a third aspect, examples of the present disclosure provide an operation method of a memory device. Referring to FIG. 16, the operation method comprises the following operations: S201, receiving, by a control logic circuit coupled with a memory cell array, a command address signal, outputting a first control signal at a first time instant, and outputting a second control signal at a second time instant, wherein the first time instant is different from the second time instant; and S202, receiving, by a clock generation circuit, a first clock signal, the first control signal and the second control signal, being pre-charged according to the first control signal, and performing frequency division processing on the first clock signal according to the second control signal to output a second clock signal, wherein the first clock signal is different from the second clock signal.

In some examples, the operation method comprises: receiving, by a first latch circuit of the control logic circuit, the command address signal and outputting the first control signal at the first time instant; receiving, by a delay circuit of the control logic circuit, the command address signal and outputting a latency count signal at the second time instant; and receiving, by a second latch circuit of the control logic circuit, the latency count signal and outputting the second control signal.

In some examples, the operation method comprises: the first control signal outputted by the first latch circuit at the first time instant starts to be in a first logic state, and according to the first control signal starting to be in the first logic state, the clock generation circuit starts to be pre-charged; and the second control signal outputted by the second latch circuit at the second time instant starts to be in an activated state, and according to the second control signal starting to be in the activated state, the clock generation circuit starts to receive the first clock signal and output the second clock signal.

In some examples, the operation method further comprises: outputting, by the delay circuit, a reset signal at a third time instant, wherein the third time instant is later than the second time instant; receiving, by the first latch circuit, the reset signal and switching the first control signal outputted at the third time instant to be in a second logic state, and according to the first control signal starting to be in the second logic state, the clock generation circuit finishes being pre-charged; and receiving, by the second latch circuit, the reset signal and switching the second control signal outputted at the third time instant to be in a non-activated state, and according to the second control signal being in the non-activated state, the clock generation circuit stops outputting the second clock signal.

In some examples, the operation method comprises: receiving, by an input buffer of the clock generation circuit, the first clock signal, the first control signal and the second control signal, starting to be pre-charged according to the first control signal, and starting to transmit the first clock signal according to the second control signal; and receiving, by a frequency divider of the clock generation circuit, the first clock signal transmitted by the input buffer, performing frequency division processing on the received first clock signal transmitted by the input buffer to output the second clock signal.

In some examples, the operation method comprises: performing, by the frequency divider, frequency division on a pair of differential clock signals of the first clock signal to output clock signals of four phases of the second clock signal, wherein the clock signals of four phases comprise a third clock signal and a third complementary clock signal having a phase difference of 180 degrees relative to each other, and a fourth clock signal and a fourth complementary clock signal having a phase difference of 180 degrees relative to each other, wherein the third clock signal and the fourth clock signal have a phase difference of 90 degrees relative to each other, and wherein two signals having a phase difference of 90 degrees from among the third clock signal, the third complementary clock signal, the fourth clock signal and the fourth complementary clock signal are used to output data from the memory cell array.

In some examples, the operation method further comprises: receiving, by a synchronization detector of the clock generation circuit, the two signals and outputting a detection signal according to the phase difference between the two signals, wherein the detection signal is to represent whether or not the two signals have a phase difference of 90 degrees relative to each other.

The memory devices utilized by the operation method of the memory device provided by various examples of the third aspect of the present disclosure are the same as or similar to the memory devices in various examples of the first aspect discussed above. Technical features that are not disclosed in detail in the examples of the present disclosure may be understood by referring to the memory devices in various examples of the first aspect discussed above, and therefore are not repeated herein.

In a fourth aspect, examples of the present disclosure provide a memory system. Referring to FIG. 17, the memory system 1002 comprises a non-volatile memory device 1004non-volatile memory device 1004 and a memory controller 1006, wherein the memory controller 1006 is coupled with the non-volatile memory device 1004non-volatile memory device 1004, and wherein the memory controller 1006 comprises at least one memory device 1070 as provided by the first aspect or the second aspect.

In examples of the present disclosure, the memory device 1070 belongs to a part of the memory controller 1006, and the memory device 1070 may comprise DRAM, SDRAM, DDR4 SDRAM, or LPDDR5 SDRAM. Here and below, discussions are made by taking DRAM as the example of the memory device 1070, which however is not used to limit the present disclosure.

In some examples, the memory controller 1006 may comprise one or more micro controller units (MCUs), field programmable gate arrays (FPGAs), digital signal processors (DSPs), application specific integrated circuits (ASICs), or the like.

In some examples, the memory system 1002 is coupled with a host 1008, and performs a variety of feedback in response to instructions of the host. In some examples, the memory controller 1006 may control the overall operation of the memory system 1002. In some examples, the memory controller 1006 is configured to control the memory device 1070 to perform operations such as read, write, refresh, etc. In some examples, the memory controller 1006 is configured to store data (e.g., a mapping table) into the memory device 1070, read the data stored in the memory device 1070, or perform the refresh operation on the memory device 1070.

In some examples, the memory controller 1006 is configured to control the non-volatile memory device 1004non-volatile memory device 1004 to perform operations such as read, write, erase, etc., and the memory controller 1006 and the non-volatile memory device 1004non-volatile memory device 1004 may also be coupled in any suitable manner.

In some examples, the non-volatile memory device 1004non-volatile memory device 1004 may comprise a device of FLASH chip (e.g., three-dimensional NAND Flash memory). The FLASH chip may be used as a storage medium of the memory system 1002 to store data, e.g., a mapping table.

In some examples, the memory controller 1006 is further configured to store, in the memory device 1070, various types of information (e.g., metadata information and the mapping table) required by the operations of the memory system 1002, and may access the non-volatile memory device 1004non-volatile memory device 1004 based on the information stored in the memory device 1070.

In some examples, the memory controller 1006 may further comprise a host interface (I/F) 10061, a memory interface (I/F) 1062, a control unit 1063, read-only memory (ROM) 1069, an error correction module 1064, a garbage collection module 1065, a wear leveling module 1066, and a bus 1060. The host interface 10061 is a connection interface connecting the host 1008 and the memory controller 1006, and the host interface 10061 allows the host and the memory controller to communicate according to a specific protocol, send read and write requests, and perform other operations. The memory interface 1062 is a connection interface between the memory controller 1006 and the non-volatile memory device 1004non-volatile memory device 1004, and the memory interface 1062 is configured to implement data transmission between the memory controller 1006 and the non-volatile memory device 1004non-volatile memory device 1004. The control unit 1063 is configured to control the memory system 1002 as a whole, and the aforementioned operations performed by the memory controller are mainly performed and completed by the control unit 1063 here. In some examples, the control unit 1063 may include, for example, a central processing unit (CPU), a micro-processing unit (MCU), or the like. The ROM 1069 generally comprises firmware or firmware program codes of the memory controller 1006. These codes are used for initializing and operating various components of the memory controller. The error correction module 1064 may further comprise an encoding unit and a decoding unit, wherein the encoding unit is configured to encode the data to be stored, so as to obtain check data, and the decoding unit is configured to decode the check data to detect and correct possible error data in the process of data transmission. The garbage collection module 1065 is configured to: after a memory space of the memory device reaches a certain threshold, read out valid data in some memory blocks, rewrite it, and then label these memory blocks in order to obtain new spare memory blocks. A general implementation of garbage collection may comprise three steps: selecting a source memory block with a small amount of valid data; finding the valid data from the source memory block; and writing the valid data to a target memory block. In this case, all data in the source memory block becomes invalid data, and the source memory block is labeled and may be used as a new spare memory block. The wear leveling module 1066 is configured to level the wear (a number of erase times) of each of the memory blocks in the memory system through data statistics and algorithms. A general implementation of wear leveling may comprise two steps: selecting a source memory block in which cold data is located; and reading valid data in the source memory block and writing the same into a memory block with a relatively large number of erase times. In this case, the valid data in the source memory block becomes invalid data, and the source memory block is labeled.

In a fifth aspect, examples of the present disclosure provide a system. Referring to FIG. 17, the system 100 comprises at least one memory system 1002 as provided by the fourth aspect, and a host 1008, wherein the memory system 1002 is coupled with the host 1008.

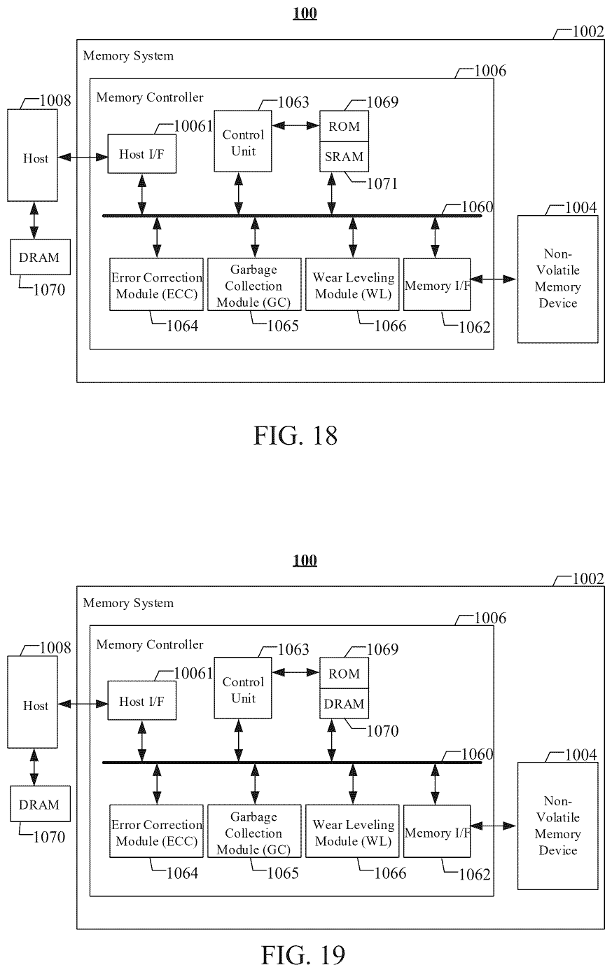

In a sixth aspect, examples of the present disclosure provide another memory system. Referring to FIG. 18, the system 100 comprises at least one memory device 1070 as provided by the first aspect or the second aspect, a memory system 1002, and a host 1008. The memory system 1002 comprises a non-volatile memory device 1004non-volatile memory device 1004 and a memory controller 1006, wherein the memory controller 1006 is coupled with the host 1008 and the non-volatile memory device 1004non-volatile memory device 1004, and wherein the host is also coupled with the at least one memory device 1070 as provided by the first aspect or the second aspect.

In the examples of the present disclosure, the memory device 1070 is located outside of the memory system 1002 and is coupled with the host 1008, and the memory device 1070 may comprise DRAM, SDRAM, DDR4 SDRAM, or LPDDR5 SDRAM. Here and below, discussions are made by taking DRAM as the example of the memory device 1070, which however is not used to limit the present disclosure.

In some examples, the memory controller 1006 may comprise one or more micro controller units (MCUs), FPGAs, DSPs, ASICs, or the like.

In some examples, the memory system 1002 is coupled with a host 1008, and performs a variety of feedback in response to instructions of the host. In some examples, the memory controller 1006 may control the overall operation of the memory system 1002. In some examples, the host 1008 is coupled with the memory device 1070, and is configured to control the memory device 1070 to perform operations such as read, write, refresh, etc. In some examples, the host 1008 is configured to store data (e.g., a mapping table) into the memory device 1070, read the data stored in the memory device 1070, or perform the refresh operation on the memory device 1070.

In some examples, the memory controller 1006 may further comprise static random-access memory (SRAM), and the SRAM 1071 is to buffer the mapping table, for example.

In some examples, the host 1008 is configured to store, in the memory device 1070, various types of information (e.g., metadata information and the mapping table) required by the operations of the memory system 1002, or read out the various types of information required by the operations of the memory system 1002 from the memory device 1070 and transmit the same to the memory controller 1006; and the memory controller 1006 is further configured to buffer, in the SRAM, various types of information required by the operations of the memory system 1002, and may access the non-volatile memory device 1004non-volatile memory device 1004 based on the information stored in the SRAM.

In some examples, the memory controller 1006 may further comprise a host interface (I/F) 10061, a memory interface (I/F) 1062, a control unit 1063, ROM 1069, an error correction module 1064, a garbage collection module 1065, a wear leveling module 1066, and a bus 1060. References may be made to the aforementioned related descriptions, for the details of the host interface (I/F) 10061, the memory interface (I/F) 1062, the control unit 1063, the ROM 1069, the error correction module 1064, the garbage collection module 1065, the wear leveling module 1066, and the bus 1060, and therefore are not repeated herein.

In a seventh aspect, examples of the present disclosure provide still another memory system. Referring to FIG. 19, the system 100 comprises at least one memory device 1070 as provided by the first aspect or the second aspect, a memory system 1002, and a host 1008. The memory system 1002 comprises a non-volatile memory device 1004non-volatile memory device 1004 and a memory controller 1006, wherein the memory controller 1006 is coupled with the host 1008 and the non-volatile memory device 1004non-volatile memory device 1004, and wherein the memory controller 1006 comprises at least one memory device 1070 as provided by the first aspect or the second aspect, and the host is also coupled with the at least one memory device 1070 as provided by the first aspect or the second aspect.

In the examples of the present disclosure, the memory device 1070 belongs to a part of the memory controller 1006 in the memory system 1002, and it also located outside of the memory system 1002 and is coupled with the host.

For other details for the memory controller comprised in the system provided by various examples of the seventh aspect of the present disclosure, references may be made to the aforementioned related descriptions, and therefore are not repeated herein.

The memory device, host, and non-volatile memory device comprised in the system provided by various examples of the seventh aspect of the present disclosure are the same as or similar to the memory device, host, and non-volatile memory device comprised in the system provided by various examples of the sixth aspect. Technical features that are not disclosed in detail in the examples of the present disclosure may be understood by referring to the memory device, host, and non-volatile memory device comprised in the system provided by various examples of the sixth aspect discussed above, and therefore are not repeated herein.

FIG. 17 shows a block diagram I of an example system 100 having a memory device according to some aspects of the present disclosure. FIG. 18 shows a block diagram II of an example system 100 having a memory device according to some aspects of the present disclosure. FIG. 19 shows a block diagram III of an example system 100 having a memory device according to some aspects of the present disclosure.

Referring to FIGS. 17, 18, and 19, the system 100 may comprise a mobile phone, a desktop computer, a laptop computer, a tablet computer, a vehicle computer, a gaming console, a printer, a positioning device, a wearable electronic device, a smart sensor, a virtual reality (VR) device, an argument reality (AR) device, or any other suitable electronic device having a memory. The system 100 may comprise a host 1008 and a memory system 1002, and the memory system 1002 is provided with one or more non-volatile memory devices 1004 and a memory controller 1006. The host 1008 may be a processor (e.g., a central processing unit (CPU)) or a system of chip (SoC) (e.g., an application processor (AP)) of an electronic device. The host 1008 may be configured to send data to the non-volatile memory device 1004non-volatile memory device 1004 or receive data from the non-volatile memory device 1004non-volatile memory device 1004.

According to some implementations, the memory controller 1006 is coupled to the non-volatile memory device 1004non-volatile memory device 1004 and the host 1008, and is configured to control the non-volatile memory device 1004non-volatile memory device 1004. The memory controller 1006 may manage data stored in the non-volatile memory device 1004non-volatile memory device 1004, and communicate with the host 1008. In some implementations, the memory controller 1006 is designed for operating in a low-duty-cycle environment, such as Secure Digital (SD) cards, Compact Flash (CF) cards, Universal Serial Bus (USB) flash drives, or other media for use in electronic devices such as personal computers, digital cameras, mobile phones, and etc.

It is to be noted that, the components/circuits/devices/signals or the like identified by the same reference numbers in the circuits in various examples of the present disclosure may be understood as the same or similar components/circuits/devices/signals, or the signals/durations/time instants or the like identified by the same reference numbers in the timing diagrams in various examples of the present disclosure may be understood as the same or similar signals/durations/time instants.

It is to be understood that references to “one example” and “an example” throughout the specification mean that particular features, structures or characteristics related to the example is included in at least one example of the present disclosure. Therefore, the use of “in one example” or “in an example” appearing everywhere in the whole specification does not necessarily refer to the same example. In addition, these particular features, structures or characteristics may be combined in one or more examples in any proper manner. It is to be understood that, in various examples of the present disclosure, sequence numbers of the above-discussed processes do not indicate an execution sequence, and the execution sequences of the various processes shall be determined by functionalities and intrinsic logics thereof, and shall not constitute any limitation on an implementation process of the examples of the present disclosure. The above serial numbers of the examples of the present disclosure are only for ease of description, and do not represent the relative merits of the examples.

The foregoing are merely preferred implementations of the present disclosure, and are not intended to limit the protection scope of the present disclosure. Equivalent structure transformations made using the contents of the specification and the drawings of the present disclosure under the inventive concept of the present disclosure, or direct/indirect applications to other related technical fields are both encompassed within the protection scope of the present disclosure.

What is claimed is:

1. A memory device, comprising:
a memory cell array;
a control logic circuit coupled with the memory cell array and configured to:
receive a command address signal, output a first control signal at a first time instant; and
output a second control signal at a second time instant, wherein the first time instant is different from the second time instant; and
a clock generation circuit configured to:
receive a first clock signal, the first control signal and the second control signal, be pre-charged according to the first control signal; and
perform frequency division processing on the first clock signal according to the second control signal to output a second clock signal, wherein the first clock signal is different from the second clock signal.

2. The memory device of claim 1, wherein the first time instant comprises a time instant when the command address signal is received or a time instant thereafter, and the first time instant is earlier than the second time instant.

3. The memory device of claim 2, wherein the control logic circuit comprises:
a first latch circuit configured to receive the command address signal, and output the first control signal at the first time instant;
a delay circuit configured to receive the command address signal, and output a latency count signal at the second time instant; and
a second latch circuit configured to receive the latency count signal, and output the second control signal.

4. The memory device of claim 3, wherein
the first latch circuit is configured such that the first control signal outputted at the first time instant starts to be in a first logic state, and according to the first control signal starting to be in the first logic state, the clock generation circuit starts to be pre-charged; and
the second latch circuit is configured such that the second control signal outputted at the second time instant starts to be in an activated state, and according to the second control signal starting to be in the activated state, the clock generation circuit starts to receive the first clock signal and output the second clock signal.

5. The memory device of claim 4, wherein
the delay circuit is further configured to receive the command address signal, and output a reset signal at a third time instant, wherein the third time instant is later than the second time instant;
the first latch circuit is further configured to receive the reset signal, and switch the first control signal outputted at the third time instant to be in a second logic state, and according to the first control signal starting to be in the second logic state, the clock generation circuit finishes being pre-charged; and
the second latch circuit is further configured to receive the reset signal, and switch the second control signal outputted at the third time instant to be in a non-activated state, and according to the second control signal being in the non-activated state, the clock generation circuit stops outputting the second clock signal.

6. The memory device of claim 5, wherein
the first latch circuit comprises a first RS latch, the first RS latch having a reset terminal to receive the reset signal, a set terminal to receive the command address signal, and an output terminal to output the first control signal; or
the second latch circuit comprises a second RS latch, the second RS latch having a reset terminal to receive the reset signal, a set terminal to receive the latency count signal, and an output terminal to output the second control signal.

7. The memory device of claim 5, wherein the delay circuit comprises:
a first clock delay unit configured to receive the command address signal, and output the latency count signal after a first preset duration; and
a second clock delay unit configured to receive the command address signal, and output the reset signal after a second preset duration,
wherein the first preset duration is a difference between the second time instant and the time instant when the command address signal is received, and the second preset duration is a difference between the third time instant and the time instant when the command address signal is received.

8. The memory device of claim 1, wherein the clock generation circuit comprises:
an input buffer configured to receive the first clock signal, the first control signal and the second control signal, start to be pre-charged according to the first control signal, and start to transmit the first clock signal according to the second control signal; and
a frequency divider configured to receive the first clock signal transmitted by the input buffer, perform frequency division processing on the received first clock signal transmitted by the input buffer to output the second clock signal.

9. The memory device of claim 8, wherein the first clock signal comprises a pair of differential clock signals, and the second clock signal comprises clock signals of four phases with a phase difference of 90 degrees in sequence;
the frequency divider is configured to perform frequency division on the pair of differential clock signals to output the clock signals of four phases, wherein the clock signals of four phases comprise a third clock signal and a third complementary clock signal having a phase difference of 180 degrees relative to each other, and a fourth clock signal and a fourth complementary clock signal having a phase difference of 180 degrees relative to each other, wherein the third clock signal and the fourth clock signal have a phase difference of 90 degrees relative to each other;
wherein two signals having a phase difference of 90 degrees from among the third clock signal, the third complementary clock signal, and the fourth clock signal and the fourth complementary clock signal are for outputting data from the memory cell array.

10. The memory device of claim 9, wherein the clock generation circuit further comprises:
a synchronization detector configured to receive the two signals, and output a detection signal according to the phase difference between the two signals, wherein the detection signal is to represent whether or not the two signals have a phase difference of 90 degrees relative to each other.

11. A memory device, comprising:
a first latch circuit including a first input terminal to receive a command address signal, and an output terminal to output a first control signal at a first time instant;
a delay circuit including an input terminal to receive the command address signal, and a first output terminal to output a latency count signal at a second time instant, wherein the first time instant is different from the second time instant;
a second latch circuit including a first input terminal connected to the first output terminal of the delay circuit to receive the latency count signal, and an output terminal to output a second control signal at the second time instant; and
a clock generation circuit including a first input terminal to receive a first clock signal, a second input terminal connected to the output terminal of the first latch circuit to receive the first control signal, a third input terminal connected to the output terminal of the second latch circuit to receive the second control signal, and an output terminal to output a second clock signal;
wherein the first control signal is to indicate a start of pre-charging, the second control signal is to indicate a start of frequency division processing on the first clock signal, and the first clock signal is different from the second clock signal.

12. The memory device of claim 11, wherein the first control signal outputted by the output terminal of the first latch circuit at the first time instant starts to be in a first logic state, and the clock generation circuit receives, at the second input terminal of the clock generation circuit, the first control signal starting to be in the first logic state and starts to be pre-charged; and
the second control signal outputted by the output terminal of the second latch circuit at the second time instant starts to be in an activated state, and the clock generation circuit receives, at the third input terminal of the clock generation circuit, the second control signal starting to be in the activated state, receives the first clock signal at the first input terminal of the clock generation circuit, and outputs the second clock signal at the output terminal of the clock generation circuit.

13. The memory device of claim 12, wherein a second output terminal of the delay circuit outputs a reset signal at a third time instant, wherein the third time instant is later than the second time instant;
a second input terminal of the first latch circuit is connected to the second output terminal of the delay circuit to receive the reset signal, and the first control signal outputted by the output terminal of first latch circuit at the third time instant is switched to be in a second logic state, and the clock generation circuit receives, at the second input terminal of the clock generation circuit, the first control signal starting to be in the second logic state and finishes being pre-charged; and
a second input terminal of the second latch circuit is connected to the second output terminal of the delay circuit to receive the reset signal, and the second control signal outputted by the output terminal of the second latch circuit at the third time instant is switched to be in a non-activated state, and the clock generation circuit receives, at the third input terminal of the clock generation circuit, the second control signal being in the non-activated state and stops outputting the second clock signal.

14. The memory device of claim 13, wherein
the first latch circuit comprises a first RS latch, the first RS latch including a reset terminal to receive the reset signal, a set terminal to receive the command address signal, and an output terminal to output the first control signal; or
the second latch circuit comprises a second RS latch, the second RS latch including a reset terminal to receive the reset signal, a set terminal to receive the latency count signal, and an output terminal to output the second control signal.

15. The memory device of claim 13, wherein the delay circuit comprises:
a first clock delay unit including an input terminal to receive the command address signal, and an output terminal to output the latency count signal after a first preset duration; and
a second clock delay unit including an input terminal to receive the command address signal, and an output terminal to output the reset signal after a second preset duration,
wherein the first preset duration is a difference between the second time instant and the time instant when the command address signal is received, and the second preset duration is a difference between the third time instant and the time instant when the command address signal is received.

16. An operation method of a memory device, comprising:
receiving, by a control logic circuit coupled with a memory cell array, a command address signal, outputting a first control signal at a first time instant, and outputting a second control signal at a second time instant, wherein the first time instant is different from the second time instant; and
receiving, by a clock generation circuit, a first clock signal, the first control signal and the second control signal, being pre-charged according to the first control signal, and performing frequency division processing on the first clock signal according to the second control signal to output a second clock signal, wherein the first clock signal is different from the second clock signal.

17. The operation method of claim 16, comprising:
receiving, by a first latch circuit of the control logic circuit, the command address signal and outputting the first control signal at the first time instant;
receiving, by a delay circuit of the control logic circuit, the command address signal and outputting a latency count signal at the second time instant; and
receiving, by a second latch circuit of the control logic circuit, the latency count signal and outputting the second control signal.

18. The operation method of claim 17, wherein:
the first control signal outputted by the first latch circuit at the first time instant starts to be in a first logic state, and according to the first control signal starting to be in the first logic state, the clock generation circuit starts to pre-charged; and
the second control signal outputted by the second latch circuit at the second time instant starts to be in an activated state, and according to the second control signal starting to be in the activated state, the clock generation circuit starts to receive the first clock signal and output the second clock signal.

19. The operation method of claim 18, further comprising:
outputting, by the delay circuit, a reset signal at a third time instant, wherein the third time instant is later than the second time instant;
receiving, by the first latch circuit, the reset signal and switching the first control signal outputted at the third time instant to be in a second logic state, and according to the first control signal starting to be in the second logic state, the clock generation circuit finishes being pre-charged; and
receiving, by the second latch circuit, the reset signal and switching the second control signal outputted at the third time instant to be in a non-activated state, and according to the second control signal being in the non-activated state, the clock generation circuit stops outputting the second clock signal.

20. The operation method of claim 16, comprising:
receiving, by an input buffer of the clock generation circuit, the first clock signal, the first control signal and the second control signal, starting to be pre-charged according to the first control signal, and starting to transmit the first clock signal according to the second control signal;
receiving, by a frequency divider of the clock generation circuit, the first clock signal transmitted by the input buffer, performing frequency division processing on the received first clock signal transmitted by the input buffer to output the second clock signal;
performing, by the frequency divider, frequency division on a pair of differential clock signals of the first clock signal to output clock signals of four phases of the second clock signal; and
receiving, by a synchronization detector of the clock generation circuit, two signals and outputting a detection signal according to a phase difference between the two signals, wherein the detection signal is to represent whether or not the two signals have a phase difference of 90 degrees relative to each other;
wherein the clock signals of four phases comprise a third clock signal and a third complementary clock signal including a phase difference of 180 degrees relative to each other, and a fourth clock signal and a fourth complementary clock signal including a phase difference of 180 degrees relative to each other, wherein the third clock signal and the fourth clock signal have a phase difference of 90 degrees relative to each other, and
wherein two signals including a phase difference of 90 degrees from among the third clock signal, the third complementary clock signal, the fourth clock signal and the fourth complementary clock signal are used to output data from the memory cell array.
